(19) United States
(12) Patent Application Publication
(10) Pub. No.: US 2024/0292713 A1
(43) Pub. Date: Aug. 29, 2024

(54) DISPLAY DEVICE AND METHOD OF MANUFACTURING THE SAME

(71) Applicant: SAMSUNG DISPLAY CO., LTD., YONGIN-SI (KR)

(72) Inventor: NAMJIN KIM, Yongin-si (KR)

(21) Appl. No.: 18/512,789

(22) Filed: Nov. 17, 2023

(30) Foreign Application Priority Data
Feb. 24, 2023 (KR) 10-2023-0025249

(51) Int. Cl. H10K 59/80; H10K 59/12

(52) U.S. Cl. CPC H10K 59/873; H10K 59/1201

(57) ABSTRACT

A display device includes a display region, a first peripheral region surrounding the display region, a second peripheral region surrounding the first peripheral region, and an outer region surrounding the second peripheral region, an emission layer disposed on a substrate and overlapping the display region, a first inorganic layer disposed on the emission layer and overlapping the first peripheral region and the second peripheral region, an organic layer disposed on the first inorganic layer and overlapping the first peripheral region, an intermediate layer disposed on the organic layer and overlapping the first peripheral region, and a second inorganic layer disposed on the intermediate layer, contacting an upper surface and a side surface of the intermediate layer, and including a material the same as that of the intermediate layer.

### CROSS-REFERENCE TO RELATED APPLICATION

This application claims priority under 35 U.S.C. § 119 to Korean Patent Application No. 10-2023-0025249, filed on Feb. 24, 2023, in the Korean Intellectual Property Office, the content of which is incorporated by reference herein in its entirety.

### TECHNICAL FIELD

The present invention relates generally to a display device.

### DISCUSSION OF RELATED ART

A display device includes an emission layer and an encapsulation layer disposed on the emission layer to protect the emission layer. To enhance an encapsulation performance of the encapsulation layer, plasma is used while the encapsulation layer is formed.

The encapsulation layer includes an organic layer. While the plasma is used, the exposed organic layer may be damaged, and may generate gases and volatile materials. For example, when the plasma is applied to the exposed organic layer, outgas such as oxygen is generated inside the organic layer, and the outgas that is not discharged may oxidize the metal electrode inside the display device. Accordingly, dark spot defects may occur in the display device.

### SUMMARY

Embodiments of the present invention provide a display device with dark spot defects being prevented, and provide a method of manufacturing the display device.

A display device according to an embodiment of the present invention may include a display region, a first peripheral region surrounding the display region, a second peripheral region surrounding the first peripheral region, and an outer region surrounding the second peripheral region, an emission layer disposed on a substrate and overlapping the display region, a first inorganic layer disposed on the emission layer and overlapping the first peripheral region and the second peripheral region, an organic layer disposed on the first inorganic layer and overlapping the first peripheral region, an intermediate layer disposed on the organic layer and overlapping the first peripheral region, and a second inorganic layer disposed on the intermediate layer, contacting an upper surface and a side surface of the intermediate layer, and including a material the same as that of the intermediate layer.

In an embodiment of the present invention, the second inorganic layer may contact the intermediate layer in the first peripheral region.

In an embodiment of the present invention, the second inorganic layer may contact a side surface of the organic layer.

In an embodiment of the present invention, the intermediate layer may contact an upper surface of the organic layer, and may not contact a side surface of the organic layer.

In an embodiment of the present invention, a planar area of the intermediate layer may be substantially the same as a planar area of the organic layer.

In an embodiment of the present invention, a planar area of the second inorganic layer may be greater than a planar area of the intermediate layer.

In an embodiment of the present invention, a planar area of the first inorganic layer may be greater than a planar area of the intermediate layer.

In an embodiment of the present invention, the second inorganic layer may contact the first inorganic layer in the second peripheral region.

In an embodiment of the present invention, the display device may further include a crack dam structure overlapping the outer region, the intermediate layer may overlap the second peripheral region, and the second inorganic layer may contact the first inorganic layer in the outer region.

A method of manufacturing a display device according to an embodiment of the present invention may include dividing the display device into a display region, a first peripheral region surrounding the display region, a second peripheral region surrounding the first peripheral region, and an outer region surrounding the second peripheral region, forming an emission layer on a substrate overlapping the display region, forming a first inorganic layer on the emission layer, the first inorganic layer overlapping the first peripheral region and the second peripheral region, forming a preliminary organic layer on the first inorganic layer, forming an intermediate layer on the preliminary organic layer, the intermediate layer overlapping the first peripheral region, forming an organic layer overlapping the intermediate layer by removing the preliminary organic layer which does not overlap the intermediate layer, and forming a second inorganic layer on the intermediate layer, the second inorganic layer including a material the same as that of the intermediate layer.

In an embodiment of the present invention, the organic layer may be formed after the intermediate layer is formed.

In an embodiment of the present invention, the preliminary organic layer which does not overlap the intermediate layer may be removed through an ashing process.

In an embodiment of the present invention, the ashing process may be performed after the intermediate layer is formed, and the second inorganic layer may be formed after the ashing process is performed.

In an embodiment of the present invention, while the preliminary organic layer which does not overlap the intermediate layer is removed, the preliminary organic layer overlapping the intermediate layer may remain by the intermediate layer.

In an embodiment of the present invention, the method may further include after the forming of the intermediate layer, treating a surface of the first inorganic layer which does not overlap the intermediate layer through a hydrogen plasma process.

In an embodiment of the present invention, the hydrogen plasma process may be performed after the intermediate layer is formed, and the second inorganic layer may be formed after the hydrogen plasma process is performed.

In an embodiment of the present invention, while the surface of the first inorganic layer is being treated, the organic layer overlapping the intermediate layer may be protected by the intermediate layer.

In an embodiment of the present invention, a planar area of the intermediate layer may be substantially the same as a planar area of the organic layer.

In an embodiment of the present invention, the second inorganic layer may contact the first inorganic layer in the second peripheral region.

In an embodiment of the present invention, the method may further include forming a crack dam structure overlapping the outer region, the intermediate layer further may overlap the second peripheral region, and the second inorganic layer may contact the first inorganic layer in the outer region.

A display device according to an embodiment of the present invention may include an intermediate layer, which protects an organic layer, included in an encapsulation layer. In the method of manufacturing the display device, the intermediate layer may protect the organic layer while plasma is used. Even if radicals, electrons, ion bombardment, etc. are applied while the plasma is used, the organic layer may not be damaged by the intermediate layer. Therefore, outgas may not be generated in the organic layer, oxidation defects of the upper electrode due to the outgas may be prevented, and dark spot defects of the display device may be prevented.

### BRIEF DESCRIPTION OF THE DRAWINGS

The accompanying drawings, which are included to provide a further understanding of the present invention, illustrate embodiments of the present invention together with the description thereof, in which:

FIG. 1 is a plan view illustrating a display device according to an embodiment of the present invention;

FIG. 2 is a circuit diagram illustrating a pixel included in the display device of FIG. 1;

FIG. 3 is a cross-sectional view illustrating a display region of the display device of FIG. 1;

FIG. 4 is a cross-sectional view illustrating a first peripheral region, a second peripheral region, and an outer region of the display device of FIG. 1;

FIG. 5 is a flowchart illustrating a method of manufacturing the display device of FIG. 4;

FIGS. 6, 7, 8, 9, 10, 11, 12, 13, 14, 15, 16, and 17 are diagrams illustrating the method of manufacturing the display device of FIG. 4; and

FIG. 18 is a cross-sectional view illustrating a display device according to an embodiment of the present invention.

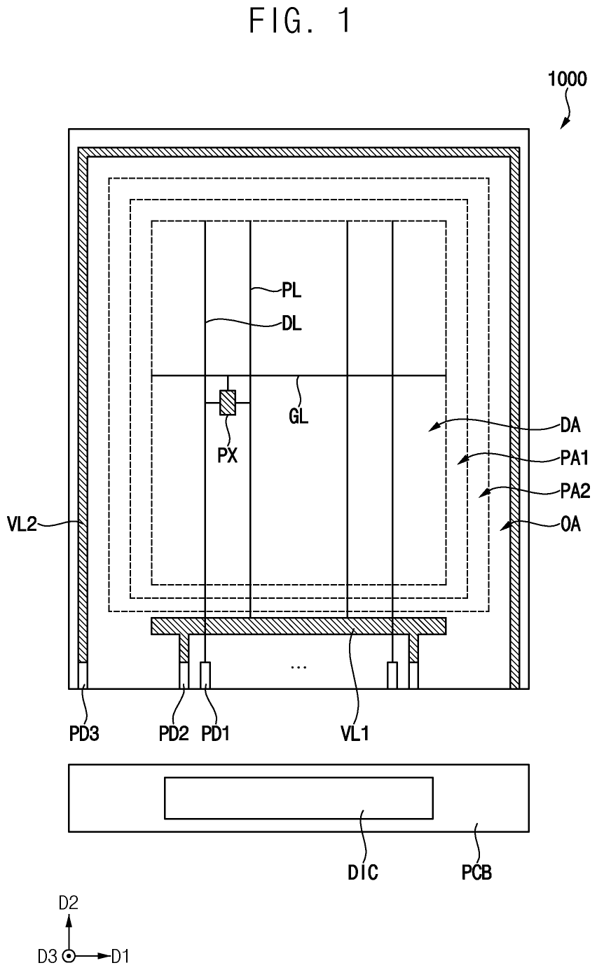

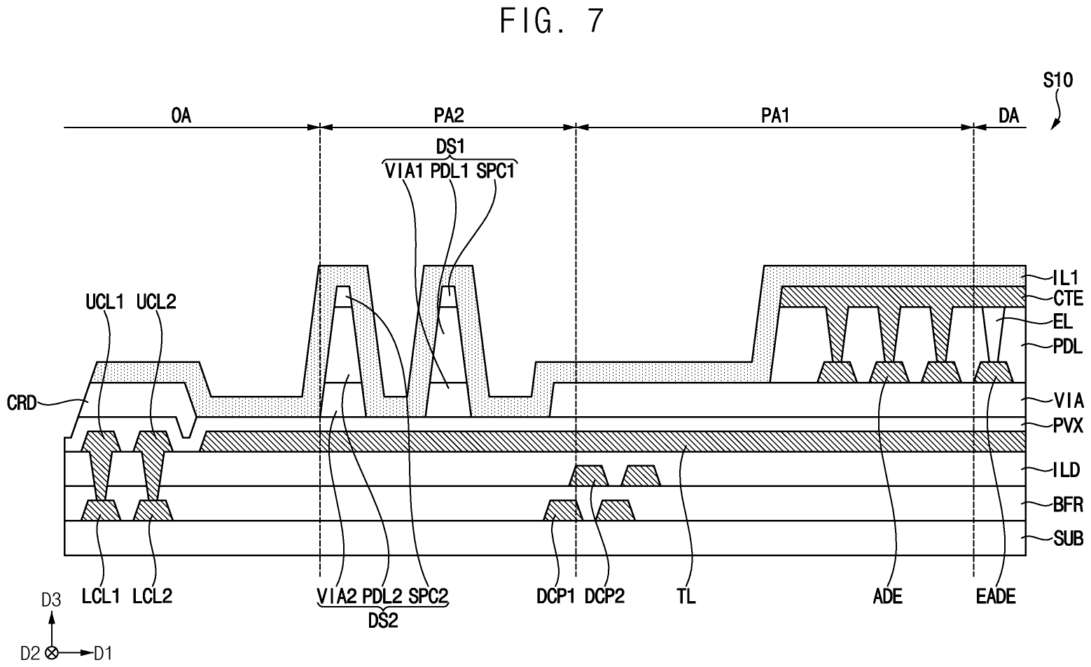

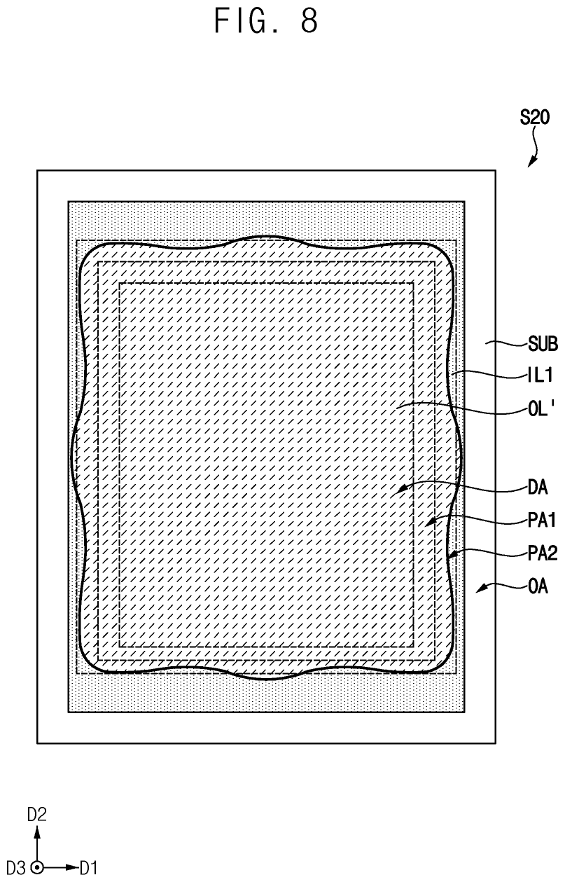

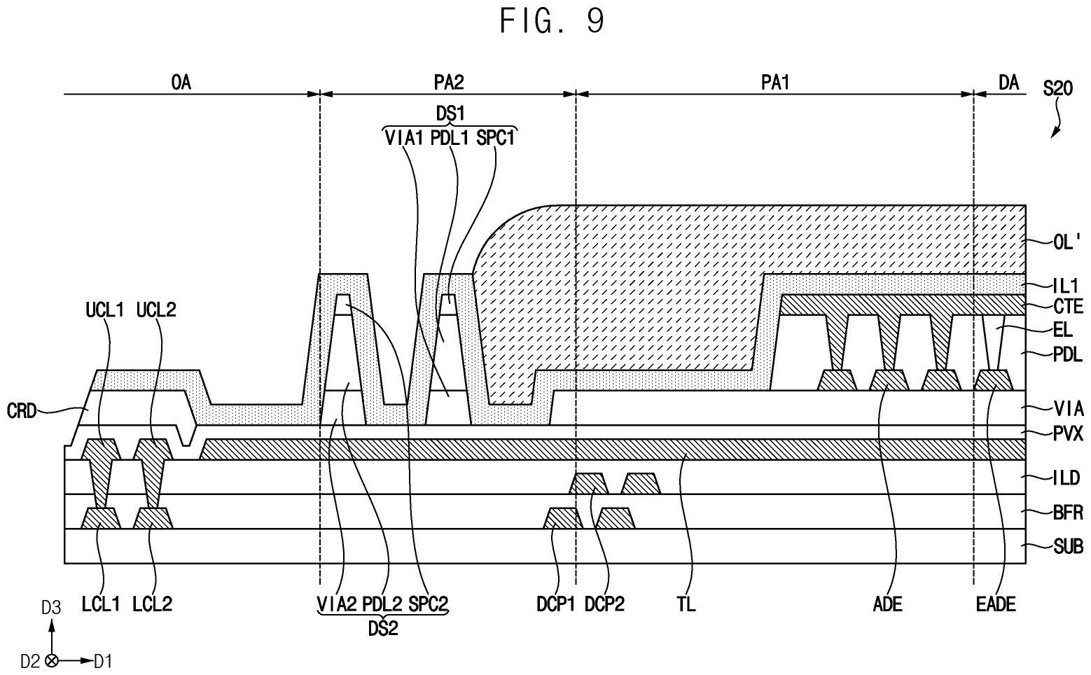

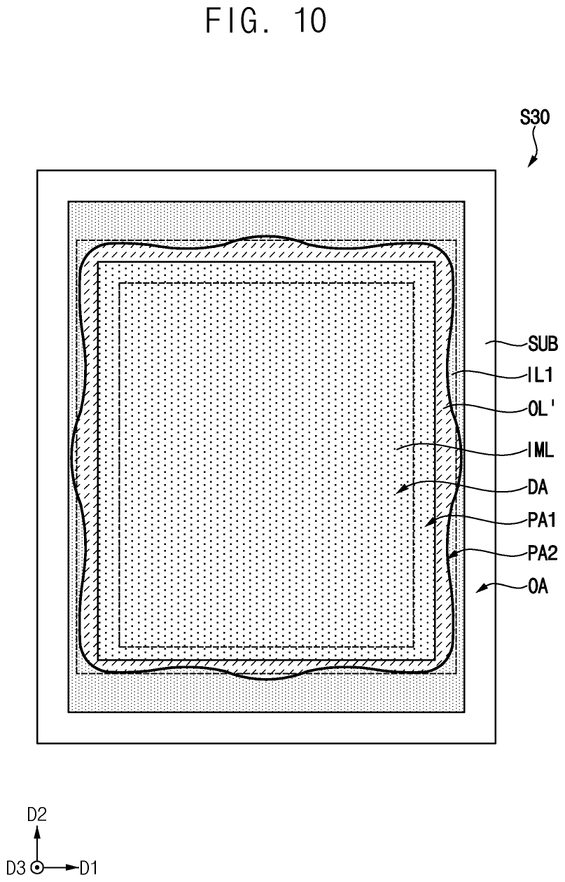

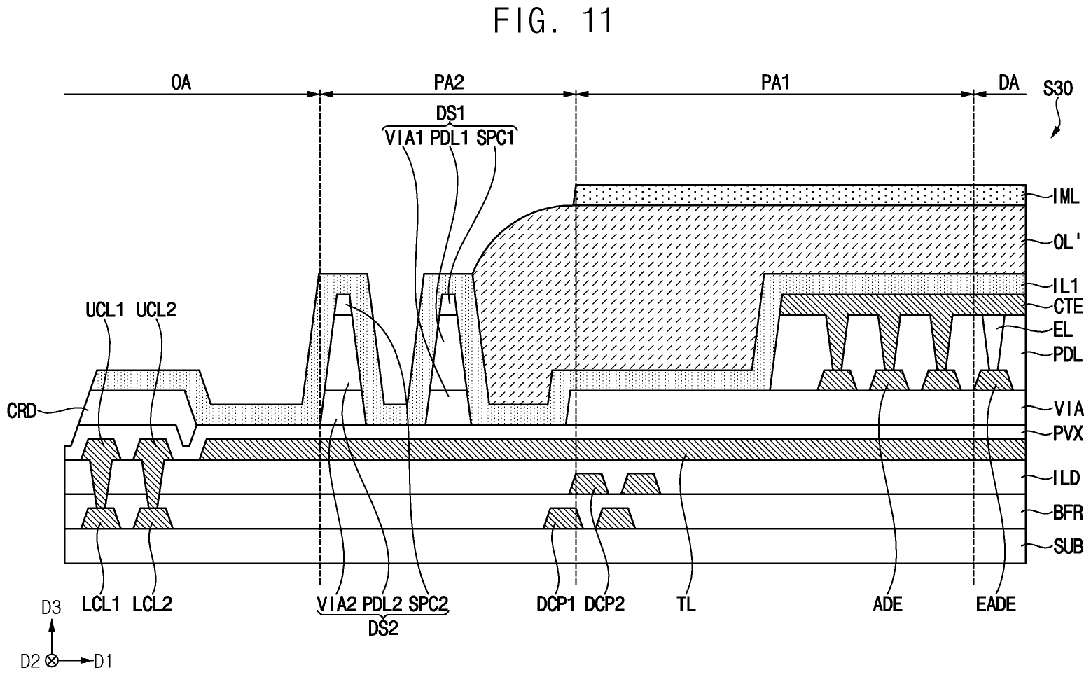

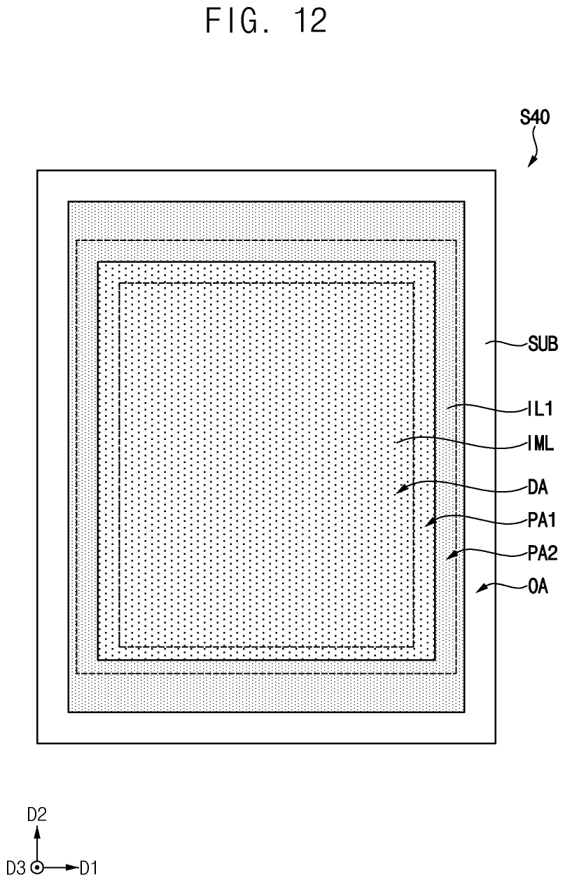

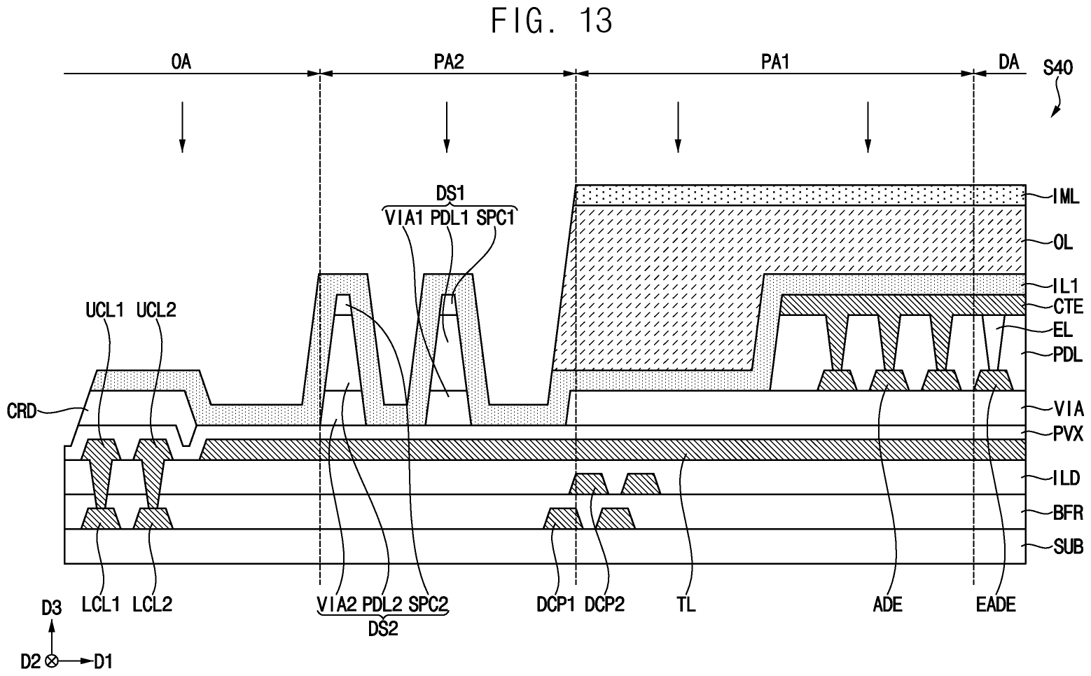

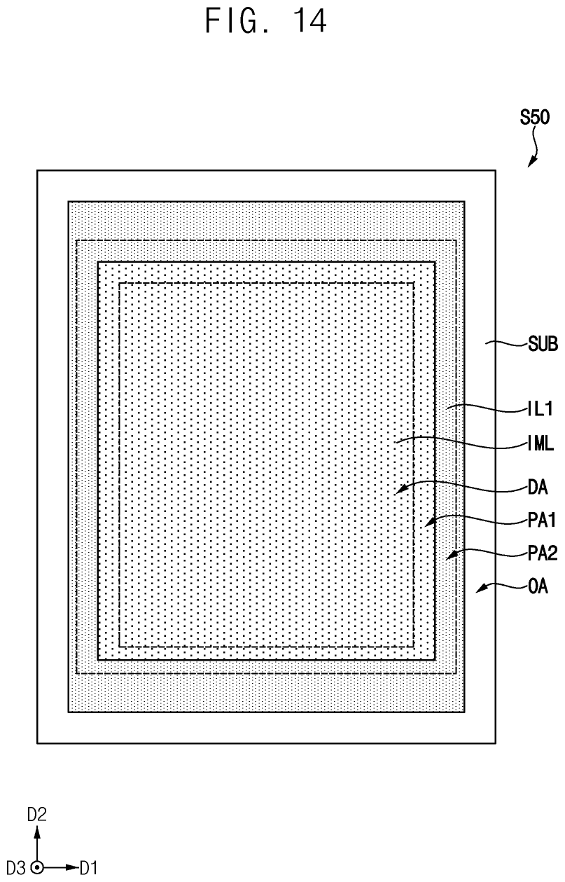

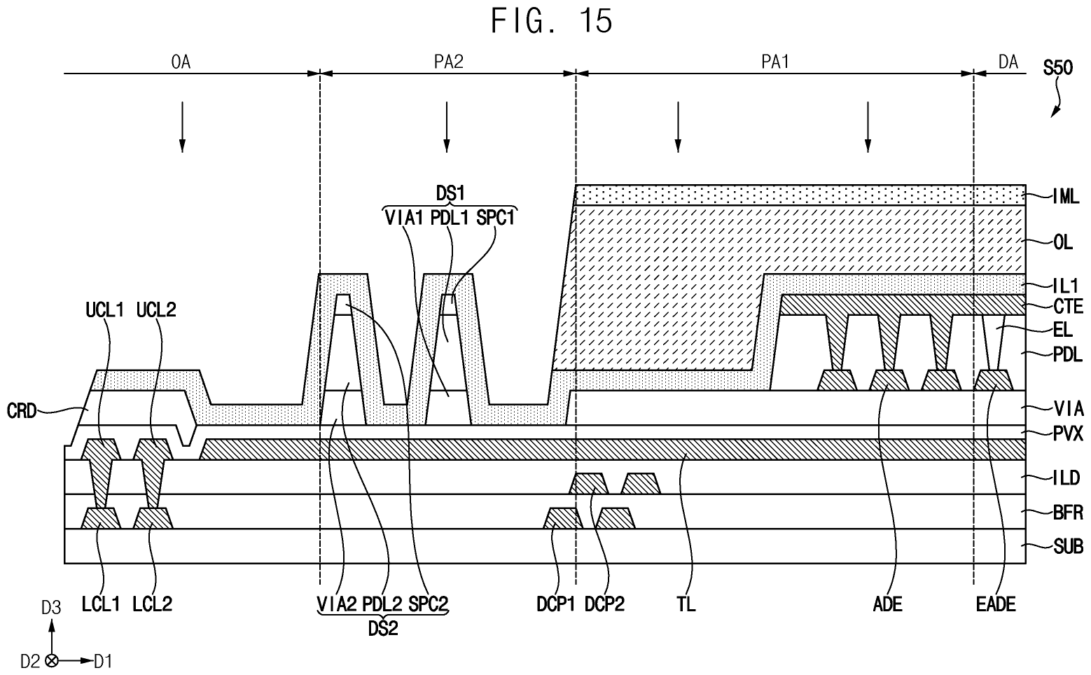

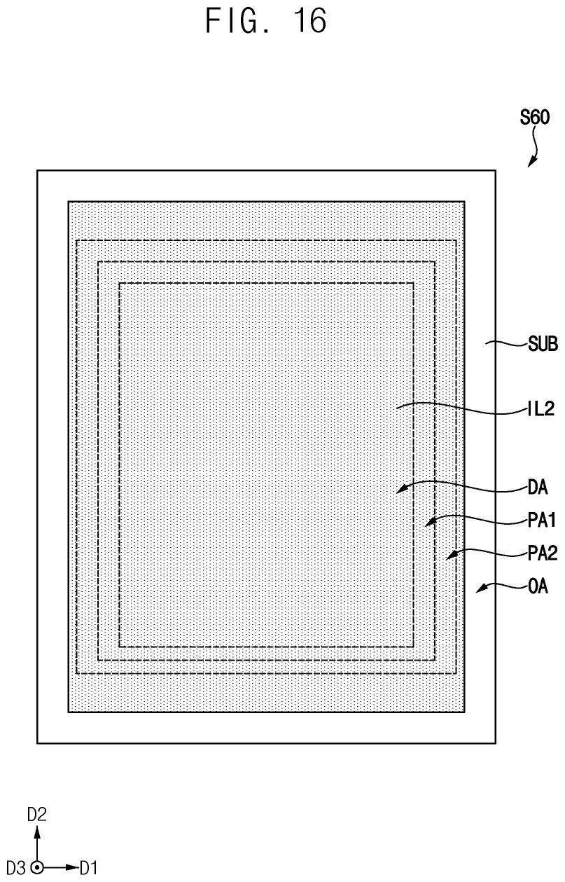

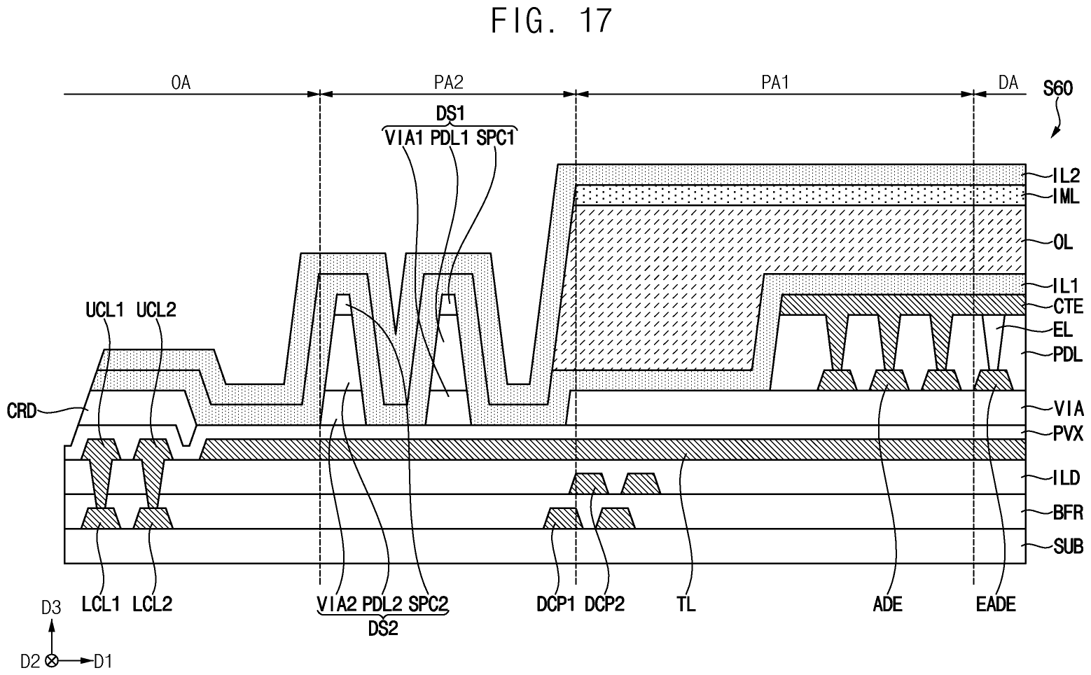

Since the drawings in FIGS. 1-18 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Illustrative, non-limiting embodiments of the present invention will be more clearly understood from the following detailed description in conjunction with the accompanying drawings.

FIG. 1 is a plan view illustrating a display device according to an embodiment of the present invention.

Referring to FIG. 1, a display device 1000 according to an embodiment of the present invention may be divided into a display region DA, a first peripheral region PA1, a second peripheral region PA2, and an outer region OA. The division of these regions may be based on their functions and locations on the display device 1000. For example, the display region DA may be located in the central area, while the first peripheral region PA1, the second peripheral region PA2, and the outer region OA may be located outside the central area, and may be regions which do not display images. However, the present invention is not limited thereto.

The display region DA may have various shapes such as, for example, a circular shape and a polygonal shape. For example, as shown in FIG. 1, the display region DA may have a rectangular shape.

In an embodiment of the present invention, the first peripheral region PA1 may be adjacent to the display region DA and may be positioned to surround at least a portion of the display region DA. The second peripheral region PA2 may be adjacent to the first peripheral region PA1 and may be positioned to surround at least a portion of the first peripheral region PA1. The outer region OA may be adjacent to the second peripheral region PA2 and may be positioned to surround at least a portion of the second peripheral region PA2. In an embodiment of the present invention, the display device 1000 may include or may be divided into a display region DA, a first peripheral region PA1 surrounding the display region DA, a second peripheral region PA2 surrounding the first peripheral region PA1, and an outer region OA surrounding the second peripheral region PA2.

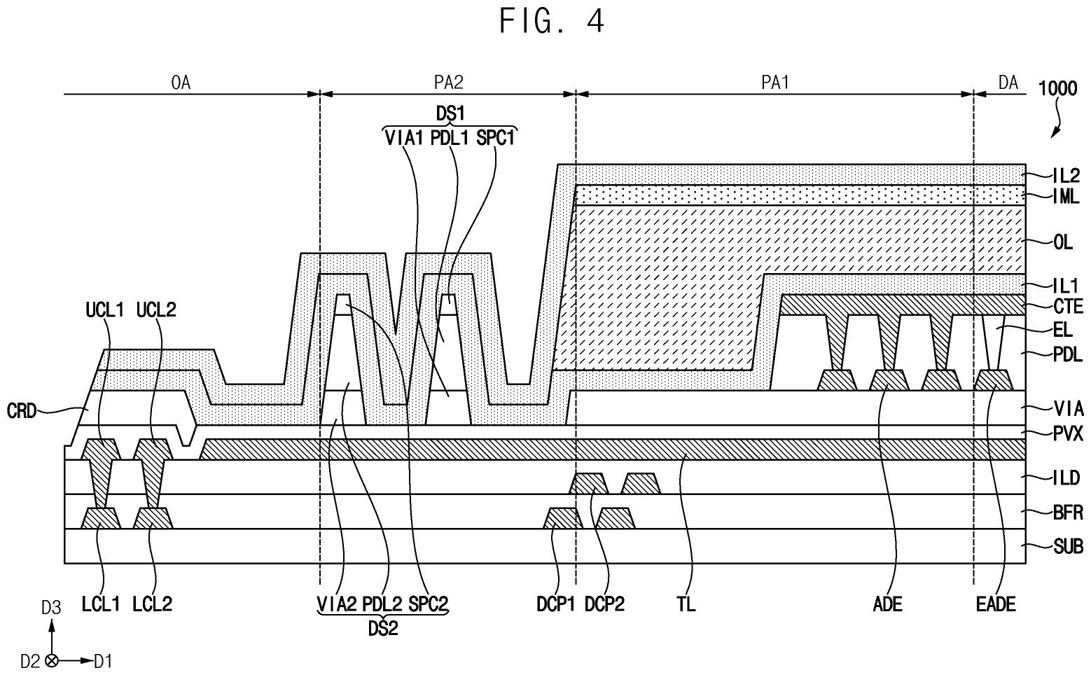

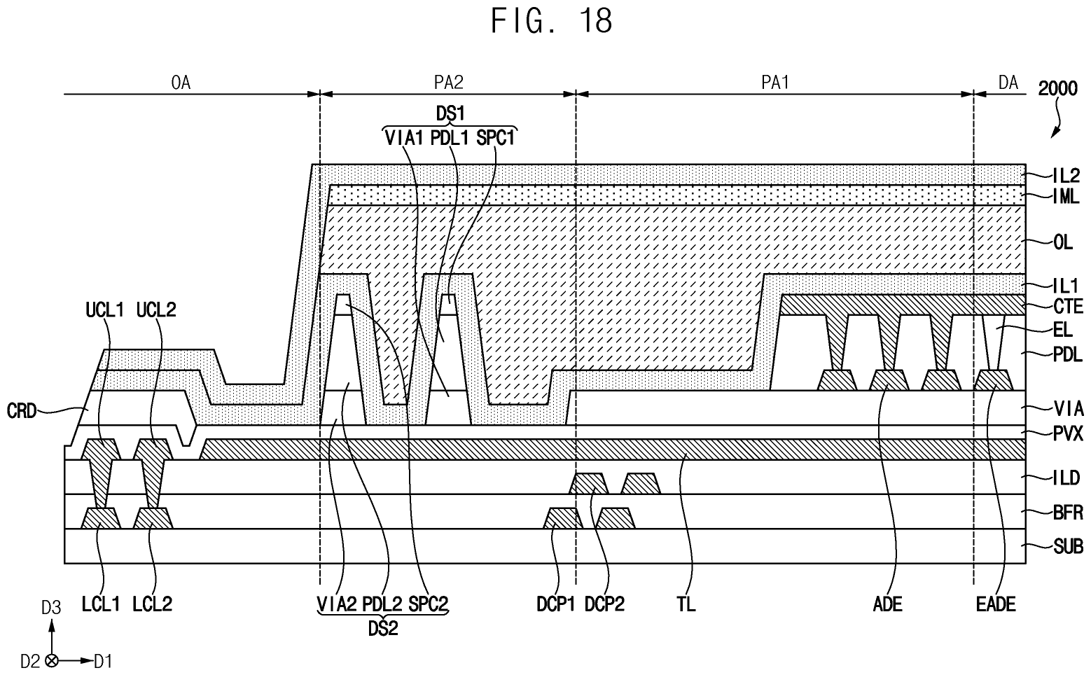

The display region DA and the first peripheral region PA1 may be partitioned by an emission layer (e.g., the emission layer EL of FIG. 4). The outer region OA and the second peripheral region PA2 may be partitioned by a dam structure (e.g., the outermost dam structure or the second dam structure DS2 of FIG. 4). A boundary between the first peripheral region PA1 and the second peripheral region PA2 may be arbitrarily defined between the display region DA and the outer region OA. For example, in an embodiment of the present invention, the boundary between the first peripheral region PA1 and the second peripheral region PA2 may be defined at an outer edge of an intermediate layer IML to be described (see FIG. 4). In an embodiment of the present invention, the boundary between the first peripheral region PA1 and the second peripheral region PA2 may be defined at a location near an outer edge of a via insulation layer VIA to be described (see FIGS. 4 and 18). However, the present invention is not limited thereto.

An image may be displayed in the display region DA. In an embodiment of the present invention, at least one pixel PX may be disposed in the display region DA. A plurality of Pixels PX may be disposed in the display region DA. For example, the pixels PX may be arranged over the whole display region DA along a first direction D1 and a second direction D2 that is orthogonal to the first direction D1. In an embodiment of the present invention, the pixels PX may be arranged in various forms such as, for example, a stripe form, a pentile form, a mosaic form, and the like, to display an image. However, the present invention is not limited thereto.

The pixel PX may be electrically connected to a data line DL, a driving voltage line PL, and a gate line GL.

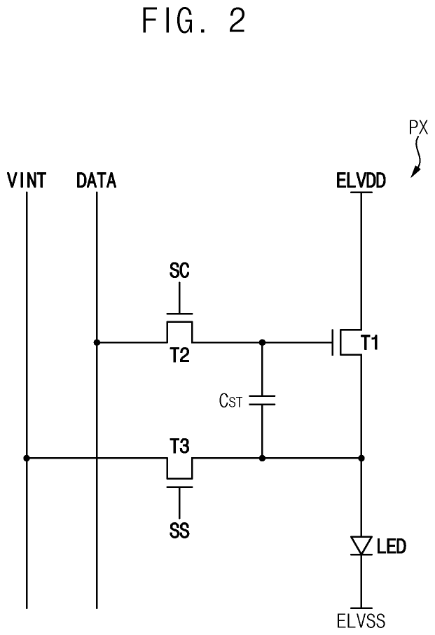

The gate driver may be disposed on at least one side (e.g., left side and/or right side) of the display device 1000. The gate driver may generate a first gate signal (e.g., the first gate signal SC in FIG. 2) and a second gate signal (e.g., the second gate signal SS in FIG. 2). The first gate signal SC and the second gate signal SS may be provided to the pixel PX through the gate line GL. For example, the first gate signal SC and the second gate signal SS may be provided to the gate terminals of the transistors located in the pixel PX.

The data driver DIC may be disposed on a printed circuit board PCB. The data driver DIC may generate a data voltage (e.g., the data voltage DATA of FIG. 2). The data voltage DATA may be provided to the pixel PX through the data line DL.

In an embodiment of the present invention, a first pad PD1, a second pad PD2, a third pad PD3, a first voltage line VL1, and a second voltage line VL2 may be disposed in the outer region OA. However, various lines, drivers, patterns, etc. for driving electrical components in the display region DA may be further disposed in the outer region OA. In an embodiment of the present invention, the first pad PD1, the second pad PD2, the third pad PD3, the first voltage line VL1, and/or the second voltage line VL2 may be disposed in the first peripheral region PA1 or the second peripheral region PA2.

In an embodiment of the present invention, the first to third pads PD1, PD2, and PD3 may be disposed in the outer region OA adjacent to the lower side of the display region DA. The first to third pads PD1, PD2, and PD3 may receive signals and/or voltages through the printed circuit board PCB. For example, the first to third pads PD1, PD2, and PD3 may receive a data voltage DATA, a first voltage ELVDD and a second voltage ELVSS, respectively.

The first pad PD1 may receive the data voltage DATA. The data voltage DATA may be provided to the pixel PX through the data line DL. For example, the first pad PD1 may be connected to the data driver DIC disposed on the printed circuit board PCB to receive the data voltage DATA.

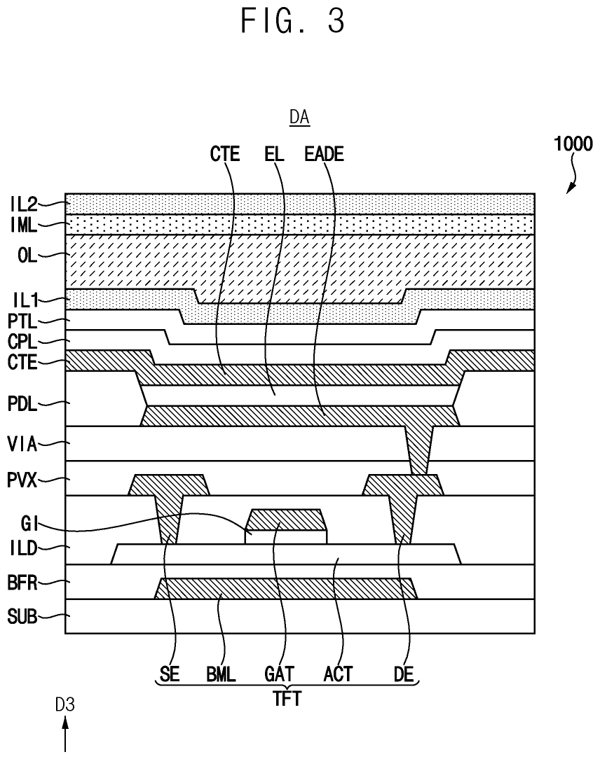

The second pad PD2 may receive a first voltage (e.g., the first voltage ELVDD of FIG. 2). The first voltage ELVDD may be provided to the pixel PX through the first voltage line VL1 and the driving voltage line PL. For example, the first voltage ELVDD may be provided to a lower electrode (e.g., the emission lower electrode EADE of FIG. 3) of the light emitting diode LED.

The third pad PD3 may receive a second voltage (e.g., the second voltage ELVSS of FIG. 2). The second voltage ELVSS may be provided to the pixel PX through an upper electrode (e.g., the upper electrode CTE of FIG. 3). For example, the third pad PD3 may be connected to the second voltage line VL2, and the second voltage ELVSS may be applied to the second voltage line VL2 to the upper electrode CTE of the light emitting diode LED.

The first voltage line VL1 may be disposed between the second pad PD2 and the display region DA, and the first voltage ELVDD may be applied to the first voltage line VL1. The second voltage line VL2 may be disposed to surround the second peripheral region PA2, and the second voltage ELVSS may be applied to the second voltage line VL2.

FIG. 2 is a circuit diagram illustrating a pixel included in the display device 1000 of FIG. 1.

Referring to FIG. 2, the pixel PX may include a first transistor T1, a second transistor T2, a third transistor T3, a storage capacitor Cst, and a light emitting diode LED. The first transistor T1, the second transistor T2, the third transistor T3, and the storage capacitor Cst may be configured to drive the light emitting diode LED.

The first transistor T1 may include a first terminal, a second terminal, and a gate terminal. The first terminal may receive the first voltage ELVDD. The second terminal may be connected to the light emitting diode LED. For example, the second terminal of the first transistor T1 may be connected to the anode electrode (e.g., emission lower electrode EADE of FIG. 3) of the light emitting diode LED. The gate terminal may be connected to the second transistor T2. The first transistor T1 may generate a driving current based on the first voltage ELVDD and the data voltage DATA.

The second transistor T2 may include a first terminal, a second terminal, and a gate terminal. The first terminal may receive the data voltage DATA. The second terminal may be connected to the first transistor T1. The gate terminal may receive the first gate signal SC. The second transistor T2 may transmit the data voltage DATA in response to the first gate signal SC.

The third transistor T3 may include a first terminal, a second terminal, and a gate terminal. The first terminal may be connected to the first transistor T1 and the light emitting diode LED. The second terminal may receive an initialization voltage VINT. The gate terminal may receive the second gate signal SS. The third transistor T3 may transmit the initialization voltage VINT in response to the second gate signal SS.

The storage capacitor Cst may include a first terminal and a second terminal. The first terminal may be connected to the gate terminal of the first transistor T1 and the second terminal of the second transistor T2. The second terminal may be connected to the first terminal of the third transistor T3 and the second terminal of the first transistor T1. The storage capacitor Cst may maintain a voltage level of the gate terminal of the first transistor T1 during an inactive period of the first gate signal SC. Also, the storage capacitor Cst may be charged with a voltage corresponding to the data voltage DATA received from the second transistor T2 during an active period.

The light emitting diode LED may include a first terminal and a second terminal. The first terminal may be connected to the second terminal of the first transistor T1. The second terminal may receive the second voltage ELVSS. The light emitting diode LED may emit light having luminance corresponding to the driving current. The first transistor T1 may control the driving current flowing through the light emitting diode LED from the driving voltage line PL in response to the voltage value stored in the storage capacitor Cst. The light emitting diode LED may include an organic light emitting diode using an organic material as an emission layer, an inorganic light emitting diode using an inorganic material as an emission layer, or the like.

Although FIG. 2 shows the pixel PX including three transistors T1, T2 and T3 and one storage capacitor Cst, the present invention is not limited thereto. For example, in an embodiment of the present invention, a pixel PX may include two or more than three transistors, and two or more storage capacitors.

FIG. 3 is a cross-sectional view illustrating a display region of the display device of FIG. 1. FIG. 4 is a cross-sectional view illustrating a first peripheral region, a second peripheral region, and an outer region of the display device of FIG. 1.

Referring to FIG. 3, the substrate SUB may include a transparent or opaque material. In an embodiment of the present invention, examples of materials that can be used as the substrate SUB may include, for example, glass, quartz, plastic, and the like. These materials may be used alone or in combination with each other. In an embodiment of the present invention, the substrate SUB may include a flexible plastic material. In addition, the substrate SUB may be composed of a single layer or multiple layers in combination with each other.

A lower metal pattern BML may be disposed on the substrate SUB. For example, the lower metal pattern BML may be formed of, for example, a metal, an alloy, a conductive metal oxide, a transparent conductive material, or the like. Examples of materials that can be used as the lower metal pattern BML may include silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These materials may be used alone or in combination with each other. In addition, the lower metal pattern BML may be formed as a single layer or as multiple layers in combination with each other.

A buffer layer BFR is disposed on the substrate SUB and may cover the lower metal pattern BML. In an embodiment of the present invention, the buffer layer BFR may be formed of an inorganic insulating material. Examples of materials that can be used as the inorganic insulating material may include silicon oxide (SiO₂), silicon nitride (Si₃N₄), and silicon oxynitride (SON). These materials may be used alone or in combination with each other. The buffer layer BFR may prevent diffusion of metal atoms or impurities from the substrate SUB into the active pattern ACT. In other words, the buffer layer BFR may be configured to reduce or block penetration of foreign materials, moisture, or ambient air from a bottom portion of the substrate SUB and may provide a flat surface on the substrate SUB. In addition, the buffer layer BFR may control a heat supply rate during a crystallization process for forming the active pattern ACT.

The active pattern ACT may be disposed on the buffer layer BFR. In an embodiment of the present invention, the active pattern ACT may be formed of a silicon semiconductor material or an oxide semiconductor material. Examples of the silicon semiconductor material that can be used for the active pattern ACT may include amorphous silicon (a-Si) and polycrystalline silicon (pc-Si). Examples of the oxide semiconductor material that can be used for the active pattern ACT may include indium gallium zinc oxide (IGZO) and indium tin zinc oxide (ITZO). In addition, the oxide semiconductor material may include an oxide of at least one material selected from, for example, indium (In), gallium (Ga), tin (Sn), zirconium (Zr), vanadium (V), hafnium (Hf), cadmium (Cd), germanium (Ge), chromium (Cr), titanium (Ti), and zinc (Zn).

A gate insulating layer GI may be disposed on the active pattern ACT. In an embodiment of the present invention, the gate insulating layer GI may be formed of an insulating material. Examples of an insulating material that can be used as the gate insulating layer GI may include silicon oxide (SiO₂), silicon nitride (Si₃N₄), and silicon oxynitride (SiON). These materials may be used alone or in combination with each other. Alternatively, the gate insulating layer GI may include a high-k dielectric material which may have a dielectric constant higher than that of the silicon oxide (SiO₂). For example, the high-k dielectric material may include at least one of, for example, hafnium oxide (HfO₂), hafnium silicon oxide (HfSiO₄), lanthanum oxide (La₂O₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaTiO₃), strontium titanium oxide (SrTiO₃), yttrium oxide (Y₂O₃), aluminum oxide (Al₂O₃), lead scandium tantalum oxide (Pb(Sc,Ta)O₃), or lead zinc niobate (Pb(Zn_{1/3}Nb_{2/3})O₃).

A gate electrode GAT may be disposed on the gate insulating layer GI. In an embodiment of the present invention, the gate electrode GAT may be formed of, for example, metal, alloy, conductive metal oxide, transparent conductive material, or the like. The gate electrode GAT may overlap a channel region of the active pattern ACT,

An interlayer insulating layer ILD may be disposed on the buffer layer BFR and the gate insulating layer GI. The interlayer insulating layer ILD may cover the gate electrode GAT. In an embodiment of the present invention, the interlayer insulating layer ILD may be formed of an insulating material. Examples of insulating materials that can be used as the interlayer insulating layer ILD may include silicon oxide (SiO₂), silicon nitride (Si₃N₄), and silicon oxynitride (SON). These materials may be used alone or in combination with each other.

The first connection electrode SE and the second connection electrode DE may be disposed on the interlayer insulating layer ILD. For example, the first connection electrode SE and the second connection electrode DE may be formed of, for example, a metal, an alloy, a conductive metal oxide, a transparent conductive material, or the like.

In an embodiment of the present invention, the first connection electrode SE and the second connection electrode DE may contact the active pattern ACT. For example, the first connection electrode SE and the second connection electrode DE may respectively be connected to a source region and a drain region of the active pattern ACT. The source region and the drain region may be doped with impurities. Here, the impurities may include N-type impurities or P-type impurities. For example, the N-type impurities may include, for example, phosphorus (P), arsenic (As), or antimony (Sb), and the P-type impurities may include, for example, aluminum (Al), boron (B), or indium (In). Accordingly, the lower metal pattern BML, the active pattern ACT, the gate electrode GAT, the first connection electrode SE, and the second connection electrode DE may constitute a transistor TFT. In an embodiment of the present invention, the lower metal pattern BML may be omitted, and the active pattern ACT, the gate electrode GAT, the first connection electrode SE, and the second connection electrode DE may constitute the transistor TFT.

A passivation layer PVX may be disposed on the interlayer insulating layer ILD. In an embodiment of the present invention, the passivation layer PVX may be formed of an inorganic insulating material. Examples of the inorganic insulating material that can be used as the passivation layer PVX may include silicon oxide (SiO₂), silicon nitride (Si₃N₄), and silicon oxynitride (SON). These materials may be used alone or in combination with each other.

A via insulation layer VIA may be disposed on the passivation layer PVX. In an embodiment of the present invention, the via insulation layer VIA may include an organic material. Examples of organic materials that can be used as the via insulating layer VIA may include photoresist, polyacrylic resin, polyimide resin, and acrylic resin. These materials may be used alone or in combination with each other. The via insulation layer VIA may be a planarization layer.

In an embodiment of the present invention, the passivation layer PVX may be omitted. In this case, the via insulating layer VIA may include an organic material and an inorganic material. Examples of materials that can be used for the via insulation layer VIA may include photoresist, polyacrylic resin, polyimide resin, acrylic resin, silicon oxide (SiO₂), silicon nitride (Si₃N₄), and silicon oxynitride (SON). These materials may be used alone or in combination with each other.

The via insulation layer VIA may overlap the display region DA. The via insulation layer VIA may provide a flat upper surface on which an emission lower electrode EADE is formed.

The emission lower electrode EADE may be disposed on the via insulating layer VIA. In an embodiment of the present invention, the emission lower electrode EADE may be electrically connected to the transistor TFT through the second connection electrode DE. In an embodiment of the present invention, the emission lower electrode EADE may be connected to the first connection electrode SE. In an embodiment of the present invention, the emission lower electrode EDE may be connected to the lower metal pattern BML through the first connection electrode SE. The emission lower electrode EADE may also be referred to as a pixel electrode or an anode electrode.

The emission lower electrode EADE may be formed of, for example, a metal, an alloy, a conductive metal oxide, a transparent conductive material, or the like. Examples of materials that can be used as the emission lower electrode EADE may include silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and the like. These materials may be used alone or in combination with each other.

The emission lower electrode EADE may be composed of a single layer or multiple layers in combination with each other. For example, the emission lower electrode EADE may be composed of three layers and may have an indium tin oxide/silver/indium tin oxide (ITO/Ag/ITO) structure.

A pixel defining layer PDL may be disposed on the via insulating layer VIA. The pixel defining layer PDL may include an organic material. Examples of organic materials that can be used as the pixel defining layer PDL may include photoresist, polyacrylic resin, polyimide resin, and acrylic resin. These materials may be used alone or in combination with each other.

An opening for forming the emission layer EL may be defined in the pixel defining layer PDL of the display region DA. For example, the pixel defining layer PDL may define a pixel area by including the opening that exposes at least a central portion of the emission lower electrode EADE.

The emission layer EL may be disposed on the emission lower electrode EADE. The upper electrode CTE may be disposed on the emission layer EL. In an embodiment of the present invention, the upper electrode CTE may include a transparent conductive material or a semi-transparent conductive material. Accordingly, light generated in the emission layer EL may be easily emitted toward a third direction D3, which is perpendicular to the first direction D1 and the second direction D2, through the upper electrode CTE. The emission layer EL may emit light based on a voltage difference between the emission lower electrode EADE and the upper electrode CTE. For example, the emission layer EL may be formed through a fine metal mask (FMM) which is a shadow mask with tiny holes for patterning side-by-side red (R), green (G), and blue (B) emitters from evaporated organic materials. The light-emitting layer EL may include an organic material and/or an inorganic material. The emission layer EL may generate one light among red light, green light, and blue light. However, the present invention is not limited thereto. For example, the emission layer EL may be provided to be connected in common with the pixels PX. In this case, the emission layer EL may provide a blue light or may provide a white light.

A capping layer CPL may be disposed on the upper electrode CTE. The capping layer CPL may have a predetermined refractive index, may resonate light emitted from the emission layer EL, and may enhance light extraction efficiency of the emission layer EL. In an embodiment of the present invention, the capping layer CPL may include an organic material and/or an inorganic material.

A protective layer PTL may be disposed on the capping layer CPL. The protective layer PTL may protect the capping layer CPL. In an embodiment of the present invention, the protective layer PTL may include an inorganic material such as lithium fluoride (LiF).

A first inorganic layer IL1 may be disposed on the protective layer PTL and may overlap the display region DA. In an embodiment of the present invention, the first inorganic layer IL1 may include an inorganic material, and may be formed by a process such as, for example, chemical vapor deposition (CVD), plasma enhanced chemical vapor deposition (PECVD), sputtering, atomic layer deposition (ALD), or the like. Examples of inorganic materials that can be used as the first inorganic layer IL1 may include silicon oxide (SiO₂), silicon nitride (Si₃N₄), silicon oxynitride (SON), aluminum oxide (Al₂O₃), aluminum nitride (AlN), aluminum oxynitride (AlON), titanium oxide (TiO₂), titanium nitride (TiN), tantalum oxide (Ta₂O₅), tantalum nitride (TaN), hafnium oxide (HfO₂), hafnium nitride (HfN), zirconium oxide (ZrO₂), zirconium nitride (ZrN), cerium oxide (CeO₂), cerium nitride (CeN), tin oxide (SnO₂), tin nitride (SnN), and magnesium oxide (MgO). These materials may be used alone or in combination with each other.

In an embodiment of the present invention, the first inorganic layer IL1 may have a structure in which a silicon nitride (Si₃N₄) layer and a silicon oxynitride (SON) layer are stacked, may be formed through a chemical vapor deposition (CVD) process, and may have a thickness of about 10,000 angstroms. “About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

An organic layer OL may be disposed on the first inorganic layer IL1 and may overlap the display region DA. In an embodiment of the present invention, the organic layer OL may include an organic material. Examples of organic materials that can be used as the organic layer OL may include polyacrylate-based resins, acrylate-based resins, polyimide-based resins, polyurea resins, and photoresists. These materials may be used alone or in combination with each other.

In an embodiment of the present invention, the organic layer OL may include an acrylate-based resin, may be formed by polymerizing a liquid monomer into a polymer, and may have a thickness of about 100,000 angstroms.

An intermediate layer IML may be disposed on the organic layer OL and may overlap the display region DA. In an embodiment of the present invention, the intermediate layer (IML) may include an inorganic material, and may be formed through a process such as, for example, a chemical vapor deposition (CVD), a plasma enhanced chemical vapor deposition (PECVD), a sputtering, an atomic layer deposition (ALD), etc. Examples of inorganic materials that can be used as the intermediate layer IML may include silicon oxide (SiO₂), silicon nitride (Si₃N₄), silicon oxynitride (SON), aluminum oxide (Al₂O₃), aluminum nitride (AlN), aluminum oxynitride (AlON), titanium oxide (TiO₂), titanium nitride (TiN), tantalum oxide (Ta₂O₅), tantalum nitride (TaN), hafnium oxide (HfO₂), hafnium nitride (HfN), zirconium oxide (ZrO₂), zirconium nitride (ZrN), cerium oxide (CeO₂), cerium nitride (CeN), tin oxide (SnO₂), tin nitride (SnN), and magnesium oxide (MgO). These materials may be used alone or in combination with each other.

In an embodiment of the present invention, the intermediate layer IML may include silicon nitride (Si₃N₄), may be formed through a chemical vapor deposition (CVD) process, and may have a thickness of about 500 angstroms.

A second inorganic layer IL2 may be disposed on the intermediate layer IML and may overlap the display region DA. In an embodiment of the present invention, the second inorganic layer IL2 may include an inorganic material, and may be formed through a process such as, for example, a chemical vapor deposition (CVD), a plasma enhanced chemical vapor deposition (PECVD), a sputtering, an atomic layer deposition (ALD), or the like. Examples of inorganic materials that can be used as the second inorganic layer IL2 may include silicon oxide (SiO₂), silicon nitride (Si₃N₄), silicon oxynitride (SON), aluminum oxide (Al₂O₃), aluminum nitride (AlN), aluminum oxynitride (AlON), titanium oxide (TiO₂), titanium nitride (TiN), tantalum oxide (Ta₂O₅), tantalum nitride (TaN), hafnium oxide (HfO₂), hafnium nitride (HfN), zirconium oxide (ZrO₂), zirconium nitride (ZrN), cerium oxide (CeO₂), cerium nitride (CeN), tin oxide (SnO₂), tin nitride (SnN), and magnesium oxide (MgO). These materials may be used alone or in combination with each other.

In an embodiment of the present invention, the second inorganic layer IL2 may include a material (e.g., silicon nitride (Si₃N₄)) the same as that of the intermediate layer IML, may be formed through a chemical vapor deposition (CVD) process, and may have a thickness of about 6,500 angstroms.

The first inorganic layer IL1, the organic layer OL, and the second inorganic layer IL2 may function as an encapsulation layer for protecting the emission layer EL. In other words, the first inorganic layer IL1, the organic layer OL, and the second inorganic layer IL2 may prevent penetration of moisture and oxygen into the emission layer EL. In addition, the display device 1000 may further include additional organic and inorganic layers. For example, in an embodiment of the present invention, at least one of the first inorganic layer IL1, the organic layer OL, or the second inorganic layer IL2 may be provided in plurality.

The first inorganic layer IL1, the organic layer OL, and the second inorganic layer IL2 may be formed using plasma. Plasma may also be used in surface treatment for enhancing adhesion between two layers in contact with each other. In the method of manufacturing the display device 1000, the intermediate layer IML may protect the organic layer OL while the plasma is used.

Accordingly, even if radicals, electrons, ion bombardment, etc. are applied while the plasma is used, the organic layer OL may not be damaged by the plasma due to the protection by the intermediate layer IML. Therefore, outgas may not be generated in the organic layer OL, oxidation defects of the upper electrode CTE due to the outgas may be prevented, and dark spot defects of the display device 1000 may be prevented.

Referring to FIG. 4, a first driving circuit pattern DCP1, a first lower clock line LCL1, and a second lower clock line LCL2 may be disposed on the substrate SUB. In an embodiment of the present invention, the first driving circuit pattern DCP1, the first lower clock line LCL1, and the second lower clock line LCL2 may be disposed on a layer the same as that of the lower metal pattern BML, and may include the same material. For example, the lower metal pattern BML, the first driving circuit pattern DCP1, the first lower clock line LCL1, and the second lower clock line LCL2 may be formed in the same process.

The first driving circuit pattern DCP1 may overlap the first peripheral region PA1 and the second peripheral region PA2 and may constitute the gate driver. The first lower clock line LCL1 and the second lower clock line LCL2 may be disposed in the outer region OA and may constitute clock lines connected to the gate driver. However, regions where the first driving circuit pattern DCP1, the first lower clock line LCL1, and the second lower clock line LCL2 are disposed are not limited thereto.

A second driving circuit pattern DCP2 may be disposed on the buffer layer BFR and may be disposed in the first peripheral region PA1. In an embodiment of the present invention, the second driving circuit pattern DCP2 may be disposed on a layer the same as that of the gate electrode GAT and may include the same material. For example, the second driving circuit pattern DCP2 and the gate electrode GAT may be formed in the same process. The second driving circuit pattern DCP2 may constitute the gate driving part together with the first driving circuit pattern DCP1.

A transmission line TL, a first upper clock line UCL1, and a second upper clock line UCL2 may be disposed on the interlayer insulating layer ILD. In an embodiment of the present invention, the transfer line TL may be electrically connected to the first connection electrode SE and/or the second connection electrode DE, and may overlap the display region DA, the first peripheral region PA1, the second peripheral region PA2 and the outer region OA. The first upper clock line UCL1 and the second upper clock line UCL2 may overlap the outer region OA. The first upper clock line UCL1 may contact the first lower clock line LCL1, and the second upper clock line UCL2 may contact the second lower clock line LCL2. However, regions where the transfer lines TL, the first upper clock line UCL1, and the second upper clock line UCL2 are disposed are not limited thereto.

A lower pattern ADE may be disposed on the via insulating layer VIA. In an embodiment of the present invention, the lower pattern ADE may be disposed on a layer the same as that of the emission lower electrode EADE, and may include the same material. For example, the lower pattern ADE and the emission lower electrode EADE may be formed in the same process.

The lower pattern ADE may be disposed in the first peripheral region PA1. The lower pattern ADE may be electrically connected to the second voltage line VL2 described with reference to FIG. 1. In FIG. 1, the second voltage line VL2 may be disposed in the outer region OA, but the present invention is not limited thereto. For example, the second voltage line VL2 may be disposed in the first peripheral region PA1 or the second peripheral region PA2. In addition, the lower pattern ADE may contact the upper electrode CTE through an opening of the pixel defining layer PDL defined in the first peripheral region PA1. Accordingly, the lower pattern ADE may transfer the second voltage ELVSS applied to the second voltage line VL2 to the upper electrode CTE. However, the region where the lower pattern ADE is disposed is not limited thereto.

A first dam structure DS1 and a second dam structure DS2 may overlap the second peripheral region PA2. For example, the first dam structure DS1 and the second dam structure DS2 may be arranged side by side in a line. The first dam structure DS1 may be more adjacent to the display region DA than the second dam structure DS2. For example, the first dam structure DS1 may be disposed between the second dam structure DS2 and the display region DA. The first dam structure DS1 may be spaced apart from the second dam structure DS2 in the second peripheral region PA2, with the first and second dam structures DS1 and DS2 each surrounding the display region DA. The first dam structure DS1 and the second dam structure DS2 may prevent the organic layer OL from flowing into the outer region OA.

The first dam structure DS1 may include a first via structure VIA1, a first pixel defining layer structure PDL1, and a first spacer structure SPC1. The second dam structure DS2 may include a second via structure VIA2, a second pixel defining layer structure PDL2, and a second spacer structure SPC2. The first and second via structures VIA1 and VIA2 may be formed together with the via insulating layer VIA, and the first and second pixel defining layer structures PDL1 and PDL2 may be formed together with the pixel defining layer PDL. The first and second spacer structures SPC1 and SPC2 may be formed together with a spacer formed in the display region DA.

The crack dam structure CRD may overlap the outer region OA. The crack dam structure CRD may prevent cracks and/or impacts from propagating to the inside. In an embodiment of the present invention, the crack dam structure CRD may be formed together with the via insulating layer VIA. For example, the via insulating layer VIA, the first via structure VIA1, the second via structures VIA2, and the crack dam structure CRD may be formed in the same process.

In an embodiment of the present invention, the first inorganic layer IL1 may further overlap the first peripheral region PA1, the second peripheral region PA2, and the outer region OA. In other words, the first inorganic layer IL1 may extend from the display region DA to the outer region OA. The part of the first inorganic layer IL1 overlapping the second peripheral region PA2 may be disposed to cover the first and second dam structures DS1 and DS2.

In an embodiment of the present invention, the organic layer OL may further overlap the first peripheral region PA1. In other words, the organic layer OL may extend from the display region DA to the first peripheral region PA1.

In an embodiment of the present invention, the intermediate layer IML may further overlap the first peripheral region PA1. In other words, the intermediate layer IML may extend from the display region DA to the first peripheral region PA1.

In an embodiment of the present invention, the second inorganic layer IL2 may further overlap the first peripheral region PA1, the second peripheral region PA2, and the outer region OA. In other words, the second inorganic layer IL2 may extend from the display region DA to the outer region OA.

In an embodiment of the present invention, a planar area of the first inorganic layer IL1 may be greater than a planar area of the intermediate layer IML and may be greater than a planar area of the organic layer OL. The “planar area” is an area of a plane, which extends in the first and second directions D1 and D2, overlapped by the described subject. In addition, a planar area of the first inorganic layer IL1 may be substantially the same as a planar area of the second inorganic layer IL2.

In an embodiment of the present invention, a planar area of the organic layer OL may be substantially the same as or greater than a planar area of the intermediate layer IML. As the intermediate layer IML functions as a mask while the organic layer OL is formed, a planar area of the organic layer OL may correspond to a planar area of the intermediate layer IML. Depending on the process used in forming the organic layer OL with the intermediate layer IML as a mask, the organic layer OL may have an inclined sidewall, a straight sidewall or an undercut sidewall. When the organic layer has a straight sidewall, the planar area of the organic layer OL may be the same as the planar area of the intermediate layer IML. When the organic layer has an undercut sidewall, the planar area of the organic layer OL may be the same as or smaller than the planar area of the intermediate layer IML. When the organic layer has an inclined sidewall, the planar area of the organic layer OL may be greater than the planar area of the intermediate layer IML. The word “substantially” used here may include a slightly deviation from the normal value caused by the manufacturing process. For example, the language “a planar area of the organic layer OL may be substantially the same as a planar area of the intermediate layer IML” may mean the planar area of the organic layer OL is exactly the same as the planar area of the intermediate layer IML, or may mean the planar area of the organic layer OL is slightly larger or slightly smaller than the planar area of the intermediate layer IML due to the manufacturing process.

In an embodiment of the present invention, a planar area of the second inorganic layer IL2 may be greater than a planar area of the intermediate layer IML. Accordingly, the second inorganic layer IL2 may cover the organic layer OL and the intermediate layer IML. For example, in an embodiment of the present invention, the organic layer OL and the intermediate layer IML may be completely overlapped by the second inorganic layer IL2.

In an embodiment of the present invention, the intermediate layer IML may contact the organic layer OL and the second inorganic layer IL2 in the display region DA and the first peripheral region PA1. For example, the intermediate layer IML may contact an upper surface of the organic layer OL and may not contact a side surface of the organic layer OL.

In an embodiment of the present invention, the second inorganic layer IL2 may contact the intermediate layer IML in the display region DA and the first peripheral region PA1. For example, the second inorganic layer IL2 may contact upper and side surfaces of the intermediate layer IML and may contact a side surface of the organic layer OL.

In addition, the second inorganic layer IL2 may contact the first inorganic layer IL1 in the second peripheral region PA2 and the outer region OA. Since the first inorganic layer IL1 and the second inorganic layer IL2 are directly in contact with each other in the second peripheral region PA2 and the outer region OA, external moisture or impurities may be prevented from propagating into the display device 1000 through the organic layer OL which is an organic material. As the intermediate layer IML has a relatively small planar area and the first inorganic layer IL1 and the second inorganic layer IL2 directly contact each other, an encapsulation performance of the second inorganic layer IL2 may be enhanced.

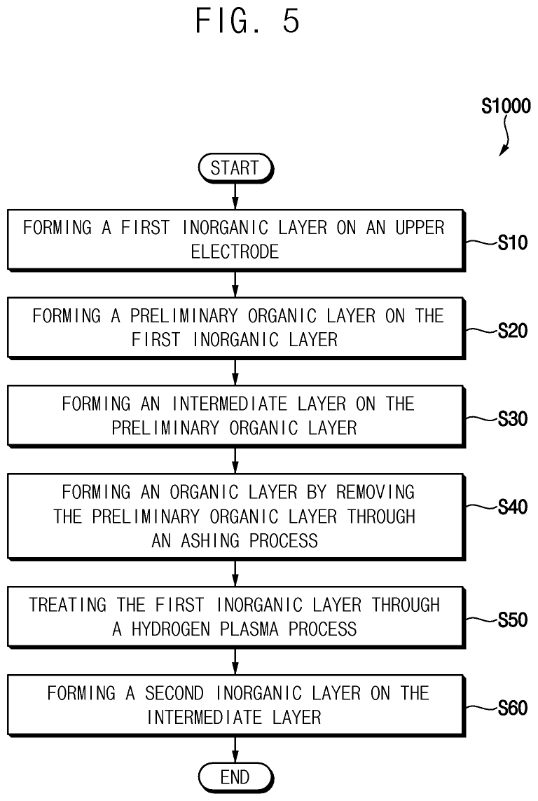

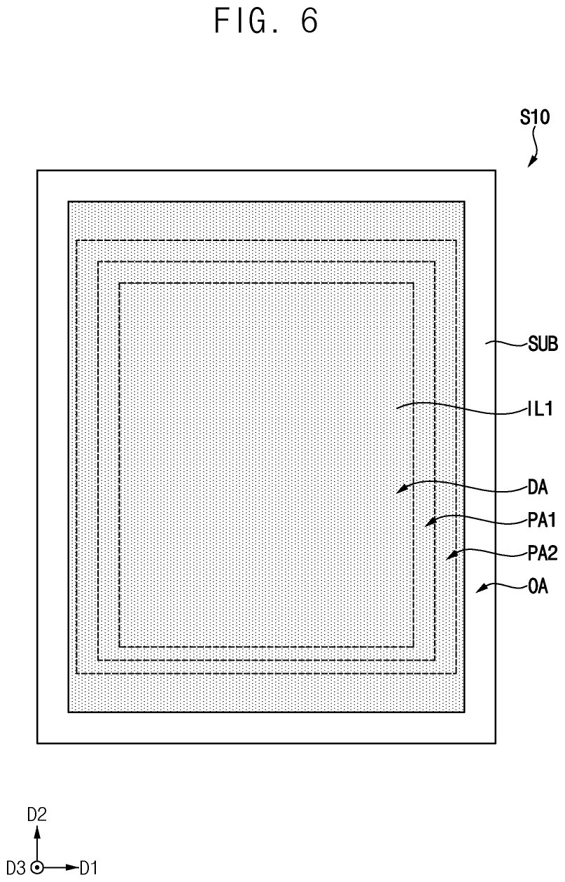

FIG. 5 is a flowchart illustrating a method of manufacturing the display device of FIG. 4. FIGS. 6, 7, 8, 9, 10, 11, 12, 13, 14, 15, 16, and 17 are diagrams illustrating the method of manufacturing the display device of FIG. 4.

Referring to FIGS. 4, 5, 6, and 7, the via insulation layer VIA overlapping the display region DA and the crack dam structure CRD overlapping the outer region OA may be formed on the substrate SUB. The first dam structure DS1 and the second dam structure DS2 overlapping the second peripheral region PA2 may be formed on the substrate SUB. In addition, the emission layer EL overlapping the display region DA may be formed, and the upper electrode CTE may be formed on the emission layer EL.

The first inorganic layer IL1 overlapping the display region DA, the first peripheral region PA1, the second peripheral region PA2, and the outer region OA may be formed on the upper electrode CTE (S10). The first inorganic layer IL1 may be formed in an appropriate region in consideration of a connection between a pad and an external device, a connection between a touch panel and a display panel, and the like.

As described above, the first inorganic layer IL1 may have a structure in which a silicon nitride (Si₃N₄) layer and a silicon oxynitride (SON) layer are stacked, may be formed through a chemical vapor deposition (CVD) process, and may have a thickness of about 10,000 angstroms.

Referring to FIGS. 4, 5, 7, 8, and 9, a preliminary organic layer OL′ may be formed on the first inorganic layer IL1 (S20). The preliminary organic layer OL′ may be mainly formed on the display region DA and the first peripheral region PA1. In addition, the preliminary organic layer OL′ may be formed of a monomer before curing, and may be reflowed to further overlap the second peripheral region PA2 (or the outer region OA). For example, an organic material including the monomer having fluidity may be cured to form the preliminary organic layer OL′. When the organic material having fluidity flows toward the outer region OA, the organic material may be blocked by the first dam structure DS1 in the second peripheral region PA2.

Referring to FIGS. 4, 5, 9, 10, and 11, the intermediate layer IML may be formed on the preliminary organic layer OL′ (S30). In an embodiment of the present invention, the intermediate layer IML may overlap the display region DA and the first peripheral region PA1. In addition, a planar area of the intermediate layer IML may be smaller than a planar area of the first inorganic layer IL1. The preliminary organic layer OL′ overlapping the display region DA and the first peripheral region PA1 may be covered in plane by the intermediate layer IML and the preliminary organic layer OL′ overlapping the second peripheral region PA2 may be exposed by the intermediate layer IML. In other words, the preliminary organic layer OL′ in the second peripheral region PA2 may not be covered and/or overlapped by the intermediate layer IML.

As described above, the intermediate layer IML may include silicon nitride (Si₃N₄), may be formed through a chemical vapor deposition (CVD) process, and may have a thickness of about 500 angstroms.

Referring to FIGS. 4, 5, 11, 12, and 13, the preliminary organic layer OL′ which does not overlap the intermediate layer IML may be removed (S40). In other words, the preliminary organic layer OL′ overlapping the intermediate layer IML may remain due to the intermediate layer IML, and the preliminary organic layer OL′ overlapping the second peripheral region PA2 may be removed. Accordingly, the organic layer OL overlapping the display region DA and the first peripheral region PA1 may be formed. In an ashing process to be described, as the intermediate layer IML functions as a mask for the preliminary organic layer OL′, the intermediate layer IML may block the plasma from removing the preliminary organic layer OL′ located under the intermediate layer IML, and thus, the preliminary organic layer OL′ overlapping the intermediate layer IML may remain.

In an embodiment of the present invention, the preliminary organic layer OL′ may be removed through an ashing process. The ashing process is a process of accelerating a gas such as oxygen (O₂), nitrous oxide (N₂O), or ammonia (NH₃) in a plasma state to remove organic materials from the preliminary organic layer OL′. In the ashing process, as the intermediate layer IML functions as a mask for the preliminary organic layer OL′, a planar area of the organic layer OL may be substantially the same as a planar area of the intermediate layer IML, and a side surface of the intermediate layer IML and a side surface of the organic layer OL may be continuously formed with each other. The preliminary organic layer OL′ which does not overlap the intermediate layer IML may overlap the second peripheral region PA2, and thus, the preliminary organic layer OL′ overlapping the second peripheral region PA2 may be removed in the ashing process.

While the ashing process is performed, as the intermediate layer IML protects the preliminary organic layer OL′ overlapping the display region DA and the first peripheral region PA1, the preliminary organic layer OL′ in these regions may not receive damage. Therefore, outgas may not be generated in the preliminary organic layer OL′, oxidation defects of the upper electrode CTE due to the outgas may be prevented, and dark spot defects of the display device 1000 may be prevented.

Referring to FIGS. 4, 5, 13, 14, and 15, a surface of the first inorganic layer IL1 which does not overlap with the intermediate layer IML may be treated through a hydrogen plasma process (S50). In other words, a surface of the first inorganic layer IL1 overlapping the second peripheral region PA2 and the outer region OA may be treated.

The hydrogen plasma process is a process of increasing the film density of the upper surface of the first inorganic layer IL1 by supplying hydrogen gas under a predetermined pressure and temperature. In the hydrogen plasma process, the hydrogen plasma gives many electrons to the surface of the first inorganic layer IL1 to reduce the oxide, and thus, makes the surface of the first inorganic layer IL1 more reactive and ready to be properly bonded to the second inorganic layer IL2. Accordingly, adhesion between the first inorganic layer IL1 and the second inorganic layer IL2 may be enhanced.

While the surface of the first inorganic layer IL1 is being treated, the organic layer OL overlapping the intermediate layer IMIL may be protected by the intermediate layer IML. Accordingly, the organic layer OL may not be damaged. Therefore, outgas may not be generated in the organic layer OL, oxidation defects of the upper electrode CTE due to the outgas may be prevented, and dark spot defects of the display device 1000 may be prevented.

Referring to FIGS. 4, 5, 15, 16, and 17 the second inorganic layer IL2 may be formed on the intermediate layer IML (S60). In an embodiment of the present invention, the second inorganic layer IL2 may overlap the display region DA, the first peripheral region PA1, the second peripheral region PA2, and the outer region OA.

In addition, a planar area of the second inorganic layer IL2 may be greater than a planar area of the intermediate layer IML and may be greater than a planar area of the organic layer OL. Accordingly, the second inorganic layer IL2 may contact the upper and side surfaces of the intermediate layer IML and may contact the side surface of the organic layer OL.

In addition, a planar area of the second inorganic layer IL2 may be substantially the same as a planar area of the first inorganic layer IL1. Accordingly, the second inorganic layer IL2 may contact the first inorganic layer IL1 in the second peripheral region PA2 and the outer region OA. Since the first inorganic layer IL1 in the second peripheral region PA2 and the outer region OA is hydrogen plasma treated, the first inorganic layer IL1 and the second inorganic layer IL2 may have good adhesion with each other in these regions. Since the second inorganic layer IL2 may contact the first inorganic layer IL1 in the second peripheral region PA2 and the outer region OA, external moisture or impurities may be prevented from propagating into the display device through the organic layer OL which is an organic material.

The second inorganic layer IL2 may include a material (e.g., silicon nitride (Si₃N₄)) the same as that of the intermediate layer IML, may be formed through a chemical vapor deposition (CVD) process, and may have a thickness of about 6,500 angstroms.

In an embodiment of the present invention, a deposition power of a chemical vapor deposition (CVD) process for forming the intermediate layer IML may be smaller than a deposition power of a chemical vapor deposition CVD process for forming the second inorganic layer IL2. In other words, a density of a material constituting the intermediate layer IML may be less than a density of a material constituting the second inorganic layer IL2. As the deposition power of the chemical vapor deposition (CVD) process for forming the intermediate layer IML is relatively small, the preliminary organic layer OL′ may not be damaged while forming the intermediate layer IML.

The display device 1000 according to an embodiment of the present invention may include the intermediate layer IML protecting the organic layer OL. In the method of manufacturing the display device 1000, the intermediate layer IML may protect the organic layer OL while plasma is used. Even if radicals, electrons, ion bombardment, etc. are applied while the plasma is used, the organic layer OL may not be damaged by the plasma due to the protection by the intermediate layer IML. Therefore, outgas may not be generated in the organic layer OL, oxidation defects of the upper electrode CTE due to the outgas may be prevented, and dark spot defects of the display device 1000 may be prevented.

FIG. 18 is a cross-sectional view illustrating a display device according to an embodiment of the present invention.

Referring to FIG. 18, the display device 2000 according to an embodiment of the present invention, may be substantially the same as the display device 1000 described with reference to FIG. 4, except for the organic layer OL, the intermediate layer IML, and the second inorganic layer IL2.

The organic layer OL may be disposed on the first inorganic layer IL1 and may overlap the display region DA, the first peripheral region PA1, and the second peripheral region PA2. For example, the organic layer OL may extend to the second peripheral region PA2 to cover the first and second dam structures DS1 and DS2. In other words, in the process of forming the organic layer OL, when an organic material, which is used to form the organic layer OL, having fluidity flows toward the outer region OA, the organic material may not be blocked by the first and second dam structures DS1 and DS2.

The intermediate layer IML may be disposed on the organic layer OL and may overlap the display region DA, the first peripheral region PA1, and the second peripheral region PA2. A planar area of the intermediate layer IML may be substantially the same as a planar area of the organic layer OL.

In an embodiment of the present invention, as shown in FIG. 4, the intermediate layer IML may extend to the first peripheral region PA1. In an embodiment of the present invention, as shown in FIG. 18, the intermediate layer IML may extend to the second peripheral region PA2. However, the present invention is not limited thereto, and the intermediate layer IML may extend to an arbitrary boundary between the display region DA and the outer region OA. Since the intermediate layer IML protects the organic layer OL, the organic layer OL may not be damaged when the plasma is used. Accordingly, outgas may not be generated in the organic layer OL, oxidation defects of the upper electrode CTE due to the outgas may be prevented, and dark spot defects of the display device 2000 may be prevented.

The second inorganic layer IL2 may be disposed on the intermediate layer IML, and may overlap the display region DA, the first peripheral region PA1, the second peripheral region PA2, and the outer region OA. Accordingly, the second inorganic layer IL2 may contact the first inorganic layer IL1 in the outer region OA. Since the second inorganic layer IL2 may contact the first inorganic layer IL1 in the outer region OA, external moisture or impurities may be prevented from propagating into the display device 2000 through the organic layer OL which is an organic material.

Although certain embodiments and implementations of the present invention have been described herein, other embodiments and modifications will be apparent from this description. Accordingly, the present invention is not limited to such embodiments, but rather to the broader scope of the appended claims and various obvious modifications and equivalent arrangements as would be apparent to a person of ordinary skill in the art.

What is claimed is:

1. A display device comprising:
a display region, a first peripheral region surrounding the display region, a second peripheral region surrounding the first peripheral region, and an outer region surrounding the second peripheral region;
an emission layer disposed on a substrate and overlapping the display region;
a first inorganic layer disposed on the emission layer and overlapping the first peripheral region and the second peripheral region;
an organic layer disposed on the first inorganic layer and overlapping the first peripheral region;
an intermediate layer disposed on the organic layer and overlapping the first peripheral region; and
a second inorganic layer disposed on the intermediate layer, contacting an upper surface and a side surface of the intermediate layer, and including a material the same as that of the intermediate layer.

2. The display device of claim 1, wherein the second inorganic layer contacts the intermediate layer in the first peripheral region.

3. The display device of claim 1, wherein the second inorganic layer contacts a side surface of the organic layer.

4. The display device of claim 1, wherein the intermediate layer contacts an upper surface of the organic layer, and does not contact a side surface of the organic layer.

5. The display device of claim 1, wherein a planar area of the intermediate layer is substantially the same as a planar area of the organic layer.

6. The display device of claim 1, wherein a planar area of the second inorganic layer is greater than a planar area of the intermediate layer.

7. The display device of claim 1, wherein a planar area of the first inorganic layer is greater than a planar area of the intermediate layer.

8. The display device of claim 1, wherein the second inorganic layer contacts the first inorganic layer in the second peripheral region.

9. The display device of claim 1, further comprising:
a crack dam structure overlapping the outer region,
wherein the intermediate layer overlaps the second peripheral region, and
the second inorganic layer contacts the first inorganic layer in the outer region.

10. A method of manufacturing a display device, the method comprising:
dividing the display device into a display region, a first peripheral region surrounding the display region, a second peripheral region surrounding the first peripheral region, and an outer region surrounding the second peripheral region;
forming an emission layer on a substrate overlapping the display region;
forming a first inorganic layer on the emission layer, the first inorganic layer overlapping the first peripheral region and the second peripheral region;
forming a preliminary organic layer on the first inorganic layer;
forming an intermediate layer on the preliminary organic layer, the intermediate layer overlapping the first peripheral region;
forming an organic layer overlapping the intermediate layer by removing the preliminary organic layer which does not overlap the intermediate layer; and
forming a second inorganic layer on the intermediate layer, the second inorganic layer including a material the same as that of the intermediate layer.

11. The method of claim 10, wherein the organic layer is formed after the intermediate layer is formed.

12. The method of claim 10, wherein the preliminary organic layer which does not overlap the intermediate layer is removed through an ashing process.

13. The method of claim 12, wherein the ashing process is performed after the intermediate layer is formed, and
the second inorganic layer is formed after the ashing process is performed.

14. The method of claim 12, wherein while the preliminary organic layer which does not overlap the intermediate layer is removed, the preliminary organic layer overlapping the intermediate layer remains by the intermediate layer.

15. The method of claim 10, further comprising:
after the forming of the intermediate layer, treating a surface of the first inorganic layer which does not overlap the intermediate layer through a hydrogen plasma process.

16. The method of claim 15, wherein the hydrogen plasma process is performed after the intermediate layer is formed, and
the second inorganic layer is formed after the hydrogen plasma process is performed.

17. The method of claim 15, wherein while the surface of the first inorganic layer is being treated, the organic layer overlapping the intermediate layer is protected by the intermediate layer.

18. The method of claim 10, wherein a planar area of the intermediate layer is substantially the same as a planar area of the organic layer.

19. The method of claim 10, wherein the second inorganic layer contacts the first inorganic layer in the second peripheral region.

20. The method of claim 10, further comprising:
forming a crack dam structure overlapping the outer region,
wherein the intermediate layer further overlaps the second peripheral region, and
the second inorganic layer contacts the first inorganic layer in the outer region.
